(19) United States
(12) Patent Application Publication
(10) Pub. No.: US 2006/0240647 A1
(43) Pub. Date: Oct. 26, 2006

(54) FILM CONTROL METHOD AND DEVICE THEREOF

(75) Inventors: Hiroshi MITSUHASHI, Kumagaya-shi (JP); Naoya Ito, Fukaya-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: TOSHIBA MATSUSHITA DISPLAY TECHNOLOGY CO., LTD., MINATO-KU (JP)

(21) Appl. No.: 11/279,977

(22) Filed: Apr. 17, 2006

(30) Foreign Application Priority Data
Apr. 25, 2005 (JP) 2005-126513

(51) Int. Cl. H01L 21/20; B23K 26/00

(52) U.S. Cl. 438/487; 438/166; 219/121.6

(57) ABSTRACT

The surface of an amorphous silicon film formed on a glass substrate is cleaned by hydrofluoric acid in a spin clean unit. The glass substrate is conveyed to a waiting unit where the glass substrate is made to wait for about 15 minutes. Active fluoride adhered on the amorphous silicon film is sublimated. The glass substrate in which the active fluoride is sublimated is conveyed into a laser annealing device where the amorphous silicon film is excimer laser annealed to reform the amorphous silicon film into a polysilicon film. The residuals of the charges in the polysilicon film generated by excimer laser annealing the surface of the amorphous silicon film with the active fluoride adhered to the surface of the amorphous silicon film can be prevented. A thin film transistor having desired TFT characteristics can be manufactured.

### INCORPORATION BY REFERENCE

The present application claims priority under 35 U.S.C. §119 to Japanese Patent Application No. 2005-126513 filed on Apr. 25, 2005. The content of the application is incorporated herein by reference in its entirety.

### FIELD OF THE INVENTION

The present invention relates to a film control method for controlling a silicon film formed on a substrate and a device thereof.

### BACKGROUND OF THE INVENTION

A structure described in, for example, Japanese Laid-Open Patent Publication No. 2000-150411 has been conventionally known as a composite type laser annealing device as a film control device of this type. The laser annealing device is a device for irradiating an amorphous silicon film deposited on a glass substrate by a plasma CVD device or the like with an excimer laser beam to reform the amorphous silicon film into a polysilicon film. The laser annealing device is provided with a cassette station in which a plurality of glass substrates on which the amorphous silicon films are deposited are stored. A spin clean unit is attached to the circumference of the cassette station. The spin clean unit spin cleans the amorphous silicon film formed on the substrate taken out from the cassette station by a conveyance robot using hydrofluoric acid (HF), and cleans and removes a surface oxide film and foreign particles or the like formed on the amorphous silicon film.

Furthermore, an annealing chamber is provided around the cassette station. The glass substrate in which the surface of the amorphous silicon film is spin cleaned by the spin clean unit is conveyed to the annealing chamber by the conveyance robot. The annealing chamber irradiates the amorphous silicon film formed on the glass substrate with an excimer laser beam and laser-anneals the amorphous silicon film to reform the amorphous silicon film into polysilicon film.

However, when the amorphous silicon film formed on the glass substrate is cleaned by the spin clean unit, hydrofluoric acid is used as a detergent in the above laser annealing device. Therefore, active fluoride as the component of the hydrofluoric acid is left on the amorphous silicon film. Even after the amorphous silicon film is laser annealed, charges are left in the polysilicon film. Therefore, there is a problem in that the threshold voltage (Vth) of the thin film transistor formed of the polysilicon film is changed and a desired transistor characteristic (TFT characteristic) is not obtained.

In order to solve the above problem, an object of the invention is to provide a film control method capable of obtaining a silicon film having a desired characteristic and a device thereof.

### SUMMARY OF THE INVENTION

A film control method of the present invention includes a clean step of cleaning a surface of a silicon film provided on a substrate using a fluorine compound, a sublimation step of sublimating fluoride contained in the fluorine compound adhered to the surface of the silicon film provided on the substrate cleaned by the clean step, and a film control step of controlling the silicon film of the substrate in which the fluoride is sublimated in the sublimation step.

After the surface of the silicon film provided on the substrate is cleaned by using the fluorine compound, the fluoride contained in the fluorine compound adhered to the surface of the silicon film of the substrate is sublimated, and the silicon film of the substrate is then controlled. The silicon film is not controlled with the fluoride contained in the fluorine compound adhered to the surface of the silicon film of the substrate. Therefore, since problems such as charges left in the silicon film can be prevented, the silicon film having the desired characteristics can be obtained.

### BRIEF DESCRIPTION OF THE DRAWINGS

FIG. 1 is an explanatory constitution diagram showing a film control device according to a first embodiment of the present invention.

FIG. 2 is an explanatory sectional view showing a liquid crystal display manufactured by the film control device.

FIG. 3 is an explanatory sectional view showing a glass substrate before being cleaned by a clean means of the film control device.

FIG. 4 is an explanatory sectional view showing the glass substrate after being cleaned by the clean means of the film control device.

FIG. 5 is an explanatory sectional view showing the glass substrate after being made to wait by a waiting means of the film control device.

FIG. 6 is a graph showing the TFT characteristics of a thin film transistor manufactured by a polysilicon film controlled by the film control device.

FIG. 7 is a graph showing the threshold characteristics of the thin film transistor when changing the holding time of the substrate by a sublimation means of the film control device.

FIG. 8 is an explanatory constitution diagram showing a film control device according to a second embodiment of the present invention.

FIG. 9 is an explanatory sectional view showing a glass substrate after being laser annealed by a laser annealing means after immediately being cleaned by the clean means.

### DETAILED DESCRIPTION OF THE PREFERRED EMBODIMENT

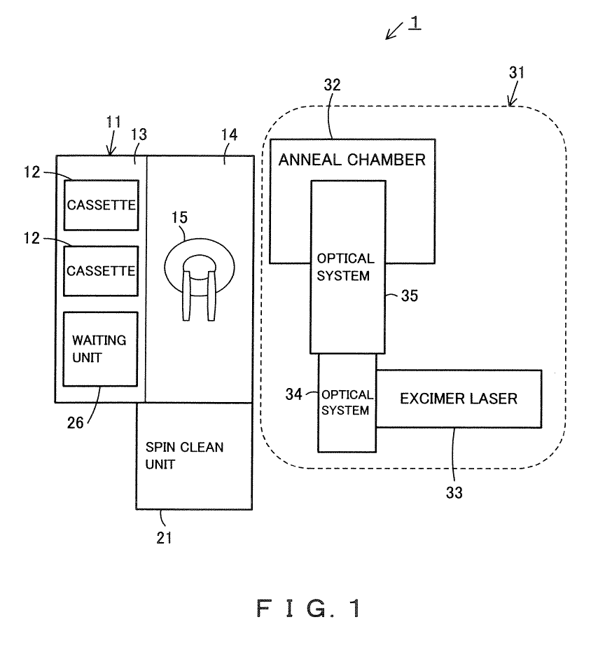

Hereinafter, the structure of a film control device according to a first embodiment of the present invention will be explained referring to FIG. 1.

In FIG. 1, numeral 1 denotes a composite type excimer laser annealing device as the film control device. The composite type excimer laser annealing device 1 is provided with a cassette station 11. A plurality of glass substrates 3 are set in the cassette station 11. Each of the glass substrates 3 has the shape of a rectangular flat plate, and has a surface on which an amorphous silicon (a-Si) film 2 is deposited and laminated by a plasma CVD device (not shown). The cassette station 11 has a long cassette setting part 13 having the shape of a rectangular plate. A plurality of cassettes 12 in which a plurality of (for example, 25 pieces) glass substrates 3 are stored are set in the cassette setting part 13.

A long substrate conveyance part 14 having the shape of a rectangular plate is provided in the cassette setting part 13 so as to be adjacent to one side of the cassette setting part 13. The substrate conveyance part 14 takes out and conveys the glass substrate 3 from the inside of the cassette 12 set in the cassette setting part 13. A conveyance robot 15 is attached to the substrate conveyance part 14. The conveyance robot 15 takes out and conveys the glass substrate 3 sequentially from the inside of the cassette 12, and conveys and stores the glass substrate 3 into the cassette 12.

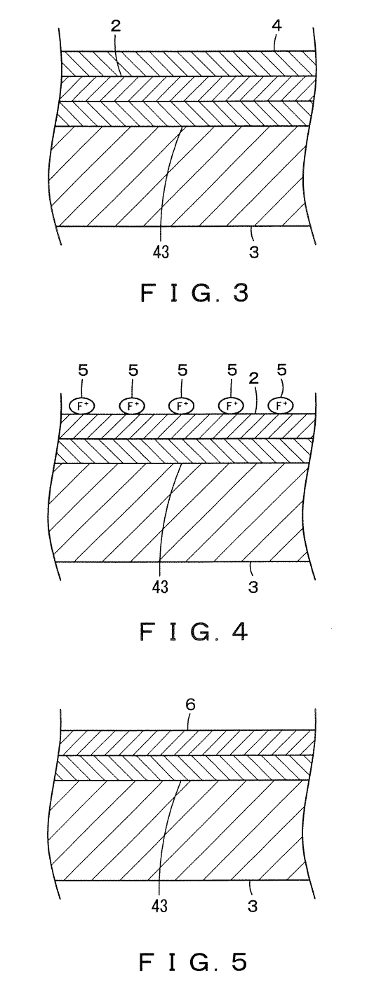

A spin clean unit 21 as a clean means is attached to one end part of the longitudinal direction of the substrate conveyance part 14. The spin clean unit 21 spin cleans the glass substrate 3 conveyed by the conveyance robot 15 of the substrate conveyance part 14. The spin clean unit 21 is set around the cassette station 11. As shown in FIG. 3, the spin clean unit 21 cleans a surface oxide layer 4 formed by the oxidation of the surface of the amorphous silicon film 2 formed on the glass substrate 3 and foreign particles or the like adhered to the surface of the amorphous silicon film 2 to remove them. Furthermore, the spin clean unit 21 uses an aqueous solution obtained by mixing hydrofluoric acid (HF) as a fluorine compound with pure water (H₂O) as a detergent. After the surface oxide layer 4 formed on the surface of the amorphous silicon film 2 formed on the glass substrate 3 is removed, the glass substrate 3 is rinsed with pure water, and the glass substrate 3 is dried by horizontally spinning and rotating the glass substrate 3.

A waiting unit 26 is attached to the cassette setting part 13 of the cassette station 11. The waiting unit 26 is a sublimation means as a waiting means for holding the glass substrate 3 spin cleaned in the spin clean unit 21 for a predetermined time and making the glass substrate 3 wait. That is, the waiting unit 26 is a means for removing charges adhered to the surface of the amorphous silicon film 2 formed on the glass substrate 3. The waiting unit 26 is provided in the cassette setting part 13, and is provided as a part of the cassette station 11. The waiting unit 26 is constituted so that the plurality of glass substrates 3 can be loaded. Furthermore, the waiting unit 26 is provided parallel to the cassette 12 set in the cassette setting part 13, and is provided at one end side of the cassette setting part 13 of the side of the spin clean unit 21.

Specifically, the waiting unit 26 makes the glass substrate 3 cleaned in the spin clean unit 21 wait and leaves the glass substrate 3 for a predetermined time, for example, for 5 minutes or more, and more preferably for 10 to 20 minutes. As shown in FIG. 4, the waiting unit 26 sublimates active fluoride (F⁺) 5 adhered to the surface of the amorphous silicon film 2 formed on the glass substrate 3. Herein, the active fluoride 5 is the component of the hydrofluoric acid in the detergent, and is a substance for generating plus charges in the polysilicon film 6 and charged in a positive charge when the active fluoride 5 enters into the polysilicon film 6 shown in FIG. 5. Furthermore, the waiting unit 26 evaporates and sublimates the molecules having the plus (+) charges adhered and left on the surface of the amorphous silicon film 2 of the glass substrate 3, that is, the active fluoride 5. Referring to the waiting unit 26, the number of the glass substrates 3 capable of being stored is set larger (the storage time of the glass substrate 3/the treatment time due to the laser annealing device 31) in view of the prevention in the reduction of the laser annealing treatment capability due to the laser annealing device 31. In other words, referring to the waiting unit 26, the number of storing steps of the glass substrate 3 is set to, for example, five pieces.

A laser annealing device 31 which is a laser annealing means as a film controlling means is attached to one side part of the substrate conveyance part 14 of the cassette station 11. The laser annealing device 31 excimer laser anneals the amorphous silicon film 2 formed on the glass substrate 3 to reform the amorphous silicon film 2 into the polysilicon (p-Si) film. The laser annealing device 31 is an excimer laser annealing means, and is set around the cassette station 11. Specifically, as shown in FIG. 5, the laser annealing device 31 melts and recrystallizes the amorphous silicon film 2 at a speed of 6 mm/s by the irradiation of an excimer laser beam to reform the amorphous silicon film 2 into the polysilicon film 6. The glass substrate 3 in which the active fluoride 5 adhered by the cleaning due to the spin clean unit 21 is sublimated by the waiting unit 26 is conveyed into the laser annealing device 31. The laser annealing device 31 irradiates the amorphous silicon film 2 formed on the glass substrate 3 with the excimer laser beam and excimer laser anneals the amorphous silicon film 2 to crystallize the amorphous silicon film 2, thereby reforming the amorphous silicon film 2 into the polysilicon film 6.

The laser annealing device 31 is provided with an annealing chamber 32 in which the glass substrate 3 cleaned by the spin clean unit 21 is conveyed and stored by the conveyance robot 15. The glass substrate 3 conveyed by the conveyance robot 15 is stored in the annealing chamber 32, and the annealing chamber 32 reforms the amorphous silicon film 2 formed on the glass substrate 3 into the polysilicon film 6. Furthermore, the laser annealing device 31 is provided with a laser oscillating device 33 as a laser oscillating means for oscillating the excimer laser beam.

Furthermore, a first optical system 34 and a second optical system 35 are attached between the laser oscillating device 33 and the annealing chamber 32. The first optical system 34 and the second optical system 35 process the excimer laser beam oscillated from the laser oscillating device 33 optically, and irradiate the surface of the amorphous silicon film 2 formed on the glass substrate 3 stored and set in the annealing chamber 32 with the excimer laser beam optically processed. Herein, the first optical system 34 is attached between the laser oscillating device 33 and the second optical system 35. Furthermore, the first optical system 34 is provided at a position into which the excimer laser beam oscillated from the laser oscillating device 33 enters.

The second optical system 35 is attached between the annealing chamber 32 and the first optical system 34. The second optical system 35 is provided at a position into which the excimer laser beam optically processed by the first optical system 34 enters. Furthermore, the second optical system 35 processes the excimer laser beam entered into the second optical system 35 optically, and irradiates the amorphous silicon film 2 formed on the glass substrate 3 in the annealing chamber 32 with the excimer laser beam optically processed.

Next, a liquid crystal display device provided with the polysilicon film 6 excimer laser annealed by the above composite type excimer laser annealing device 1 will be explained.

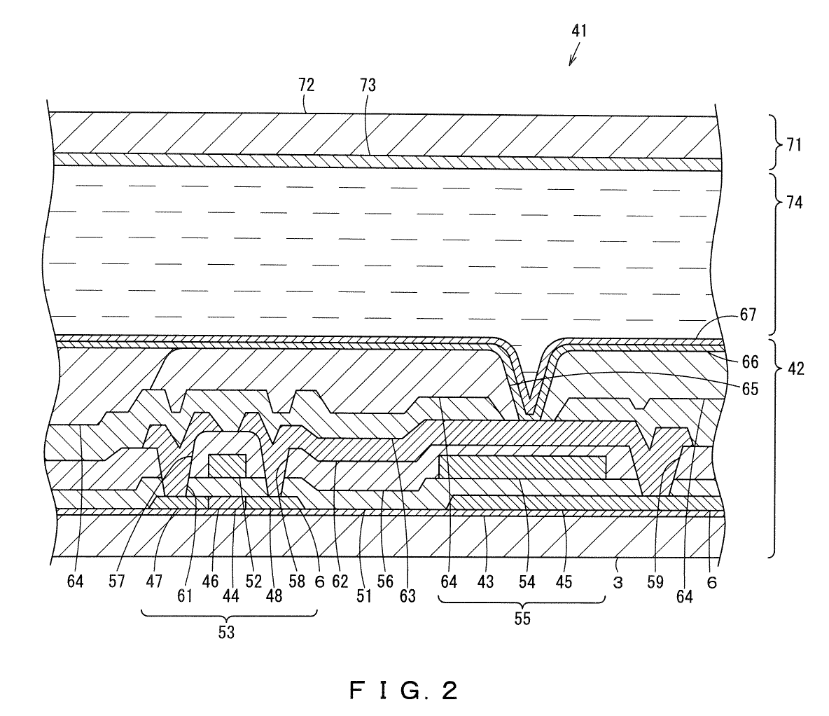

In FIG. 2, numeral 41 denotes a liquid crystal display element as the liquid crystal display device. The liquid crystal display element 41 is a low-temperature polysilicon thin film transistor (TFT) liquid crystal display. The liquid crystal display element 41 is provided with an array substrate 42 having the shape of a generally rectangular flat plate. The array substrate 42 is provided with the glass substrate 3 being nearly transparent and having insulation. An insulating undercoat layer 43 for preventing the diffusion of impurities from the glass substrate 3 is deposited on the surface of the glass substrate 3. The under coat layer 43 has a silicon nitride film (SiNₓ) and a silicon oxide film (SiOₓ), and is deposited and formed by a plasma CVD method.

A semiconductor layer 44 as an active layer and a capacity part 45 are provided like an island on the undercoat layer 43. Each of the semiconductor layer 44 and capacity part 45 is composed by the polysilicon film 6. Herein, a channel region 46 is provided at the central part of the semiconductor layer 44, and a source region 47 and a drain region 48 are respectively provided at both sides of the channel region 46.

Furthermore, a gate oxide film 51 as a gate insulating film such as the silicon oxide film having insulation is deposited on the under coat layer 43 containing the semiconductor layer 44 and the capacity part 45. A gate electrode 52 is laminated and formed so as to face the channel region 46 of the semiconductor layer 44 on the gate oxide film 51. The gate electrode 52 is made of a molybdenum-tungsten alloy (MoW) or the like. A p-type thin film transistor 53 as a switching element is formed by the gate electrode 52, the gate oxide film 51 and the semiconductor layer 44.

A capacity wiring part 54 is laminated and formed so as to face the capacity part 45 on the gate oxide film 51. The capacity wiring part 54 is made of a molybdenum-tungsten alloy (MoW) or the like, and is formed by the same process as that of the gate electrode 52. Also, the capacity wiring part 54 is made of the same material as that of the gate electrode 52. An auxiliary capacity 55 is formed by the capacity wiring part 54, the gate oxide film 51 and the capacity part 45.

An interlayer insulating film 56 formed by the silicon oxide film or the like is deposited on the gate oxide film 51 containing the gate electrode 52 and the capacity wiring part 54. First contact holes 57, 58, and 59 are formed in the interlayer insulating film 56 and the gate oxide film 51. The first contact holes 57, 58, and 59 pass through the interlayer insulating film 56 and the gate oxide film 51 and a recommunicated with the source region 47, drain region 48 and capacity part 45 of the semiconductor layer 44. A source electrode 61 is laminated on the interlayer insulating film 56 containing the first contact hole 57 penetrating to the source region 47 of the semiconductor layer 44. Therefore, the source electrode 61 is electrically connected to the source region 47 of the semiconductor layer 44.

A drain electrode 62 is laminated on the interlayer insulating film 56 containing the first contact hole 58 penetrating to the drain region 48 of the semiconductor layer 44 and the first contact hole 59 penetrating to the capacity part 45. Therefore, the drain electrode 62 is electrically connected to the drain region 48 of the semiconductor layer 44, and is electrically connected to the capacity part 45. Therefore, the drain region 48 of the semiconductor layer 44 is electrically connected to the capacity part 45 by the drain electrode 62. Herein, the source electrode 61 and the drain electrode 62 is made of low-resistance metal or the like such as aluminum (Al) or the like.

A passivation film 63 as a protective film is laminated on the interlayer insulating film 56 containing the source electrode 61 and the drain electrode 62. A color filter layer 64 sequentially colored to colors of more than at least the three primary colors of light, for example, three colors of red, blue and green is laminated and deposited on the passivation film 63. A second contact hole 65 passing through the color filter layer 64 and the passivation film 63 and penetrating to the drain region 48 is formed in the color filter layer 64 and the passivation film 63.

Furthermore, a pixel electrode 66 is laminated and deposited on the color filter layer 64 containing the second contact hole 65. The pixel electrode 66 is electrically connected to the drain electrode 62 via the second contact hole 65. An oriented film 67 is laminated and deposited on the pixel electrode 66.

A counter substrate 71 is arranged so as to face the oriented film 67. The counter substrate 71 is provided with a glass substrate 72 being nearly transparent and having insulation. A counter electrode 73 is laminated and provided on a surface of the glass substrate 72 facing the oriented film 67. A liquid crystal layer 74 composed by injecting and sealing a liquid crystal composition is formed as a light modulation layer between the counter electrode 73 and the oriented film 67 of the array substrate 42.

Next, the operation of the above composite type excimer laser annealing device will be explained.

After the undercoat layer 43 is first formed on one principal surface of the glass substrate 3 by the plasma CVD method or the like, the amorphous silicon film 2 is deposited on the undercoat layer 43.

Then, the glass substrate 3 on which the amorphous silicon film 2 is deposited is stored in the cassette 12, and the cassette 12 in which the glass substrate 3 is stored is set in the cassette setting part 13 of the cassette station 11.

In this state, the glass substrate 3 is taken out from the cassette 12 set in the cassette setting part 13 by the conveyance robot 15 in the substrate conveyance part 14 of the cassette station 11, and the glass substrate 3 is conveyed into the spin clean unit 21.

The glass substrate 3 conveyed into the spin clean unit 21 is cleaned by the detergent obtained by mixing hydrofluoric acid (HF) with pure water (H₂O) while the glass substrate 3 is horizontally rotated in the spin clean unit 21. At this time, as shown in FIG. 3, the surface oxide layer 4 formed on the surface of the amorphous silicon film 2 formed on the glass substrate 3, the foreign particles adhered to the surface of the amorphous silicon film 2 or the like are removed by the cleaning of the glass substrate 3 due to the spin clean unit 21.

Furthermore, after the glass substrate 3 conveyed into the spin clean unit 21 is cleaned in the spin clean unit 21, the glass substrate 3 is rinsed by pure water and is dried.

Then, the glass substrate 3 cleaned and dried by the spin clean unit 21 is taken out from the inside of the spin clean unit 21 by the conveyance robot 15, and is conveyed into the waiting unit 26 via the substrate conveyance part 14. The glass substrate 3 is left and is made to wait in the waiting unit 26 for a predetermined time, for example, for 15 minutes. As shown in FIG. 4, the active fluoride 5 adhered to the surface of the amorphous silicon film 2 formed on the glass substrate 3 is sublimated.

Then, the glass substrate 3 made to wait in the waiting unit 26 is taken out from the waiting unit by the conveyance robot 15. The glass substrate 3 is then conveyed into the annealing chamber 32 of the laser annealing device 31 via the substrate conveyance part 14, and is set in the annealing chamber 32.

In this state, the excimer laser beam is oscillated from the laser oscillating device 33 of the laser annealing device 31. The excimer laser beam is optically processed by the first optical system 34 and the second optical system 35, and the amorphous silicon film 2 formed on the glass substrate 3 in the annealing chamber 32 is irradiated with the excimer laser beam. As shown in FIG. 5, the amorphous silicon film 2 is laser annealed, and thereby the amorphous silicon film 2 is crystallized to reform the amorphous silicon film 2 into the polysilicon film 6.

Then, the glass substrate 2 in which the polysilicon film 6 is formed in the annealing chamber 32 is taken out from the inside of the annealing chamber by the conveyance robot 15, and the glass substrate 2 is conveyed into the predetermined cassette 12 set in the cassette setting part 13 of the cassette station 11 via the substrate conveyance part 14.

Then, the cassette 12 in which the glass substrate 3 is stored is taken out from the cassette setting part 13 of the cassette station 11. The polysilicon film 6 formed on the glass substrate 3 in the cassette 12 is patterned by photolithography and etching, and the gate oxide film 51 is then formed on the undercoat layer 43 containing the polysilicon film 6 by the plasma CVD method or the like.

Furthermore, after the gate electrode 52 and the capacity wiring part 54 are formed on the gate oxide film 51 by sputtering and etching, the source region 47 and the drain region 48 are formed at both sides of the polysilicon film 6 as the semiconductor layer 44 by photolithography and etching to form the thin film transistor 53. At this time, the source region 47 and the drain region 48 are formed by using resist (not shown) at the time of etching processing the gate electrode 52 as a mask and by ion-doping impurities such as boron (B) and phosphorous (P). The channel region 46 is formed at the central part of the polysilicon film 6 located below the gate electrode 52.

Then, after the interlayer insulating film 56 is formed on the gate oxide film 51 containing the gate electrode 52 and the capacity wiring part 54, the first contact hole 57, 58, and 59 are formed. After the low-resistance metal is sputtered on the inter layer insulating film 56 containing the first contact holes 57, 58, and 59, the low-resistance metal is patterned, and the source electrode 61 and the drain electrode 62 are formed.

After the passivation film 63 is formed on the interlayer insulating film 56 containing the source electrode 61 and the drain electrode 62, and the color filter layer 64 is then formed, the second contact hole 65 is formed.

After a transparent conductor layer such as ITO (Indium Tin Oxide) is deposited and on the color filter layer 64 containing the second contact hole 65, and is etched to form the pixel electrode 66, the oriented film 67 is formed on the color filter layer 64 containing the pixel electrode 66.

After the counter electrode 73 of the counter substrate 71 is then bonded to the oriented film 67 so as to face the oriented film 67, the liquid crystal composition is injected and sealed between the counter electrode 73 of the counter substrate 71 and the oriented film 67 of the array substrate 42. Thereby, the liquid crystal layer 74 is formed, and the liquid crystal display element 41 is produced.

As described above, according to the above first embodiment, when the glass substrate 3 cleaned by the spin clean unit 21 is immediately conveyed to the annealing chamber 32 of the laser annealing device 31 as it is, and the amorphous silicon film 2 formed on the glass substrate 3 is laser annealed to reform the amorphous silicon film 2 into the polysilicon film 6, the amorphous silicon film 2 is laser annealed with the active fluoride 5 adhered to the surface of the amorphous silicon film 2 and left. Therefore, the charges are left in the polysilicon film 6 even after the laser anneal.

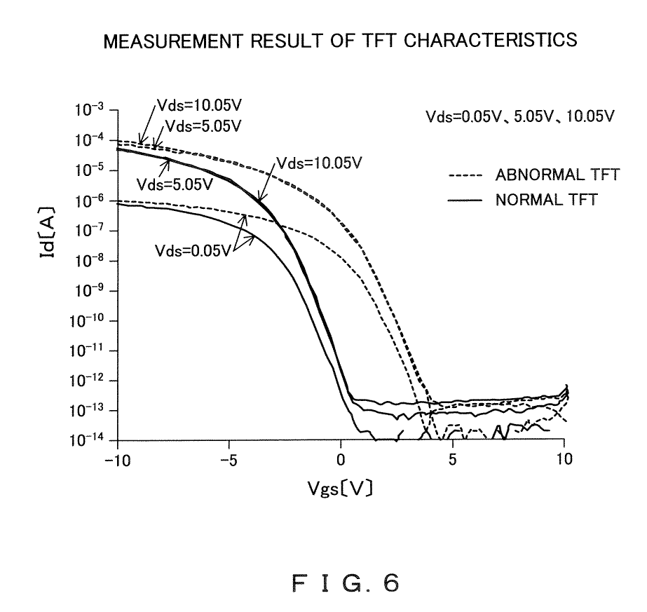

As a result, as shown in FIG. 6, a gate source voltage (V_{gs}) to a drain current (I_{d}) when the drain source voltage (V_{ds}) of the thin film transistor 53 formed from the polysilicon film 6 is sequentially changed at stages such as 0.05 V, 5.05 V, 10.05 V is shifted to the plus (+) side. Therefore, since the threshold voltage (Vₜₕ) of the thin film transistor 53 is changed, the desired TFT characteristics cannot be obtained, and the thin film transistor 53 having no normal TFT characteristics is formed.

Then, after the surface of the amorphous silicon film 2 formed on the glass substrate 3 by the spin clean unit 21 is cleaned by the hydrofluoric acid aqueous solution, the glass substrate 3 is conveyed to the waiting unit 26 by the conveyance robot 15, and is made to wait for about 15 minutes. The active fluoride 5 adhered to the surface of the amorphous silicon film 2 formed on the glass substrate 3 is sublimated, and the charges left on the amorphous silicon film 2 are removed.

As a result, the glass substrate 3 in which the active fluoride 5 adhered to the surface of the amorphous silicon film 2 by making the glass substrate 3 wait in the waiting unit 26 is sublimated is conveyed to the annealing chamber 32 of the laser annealing device 31 by the conveyance robot 15. The amorphous silicon film 2 formed on the glass substrate 3 is excimer laser annealed in the annealing chamber 32 to reform the amorphous silicon film 2 into the polysilicon film 6. Therefore, the residuals of the charges in the polysilicon film 6 generated by laser annealing the amorphous silicon film 2 formed on the glass substrate 3 with the active fluoride 5 adhered to the surface of the amorphous silicon film 2 can be prevented.

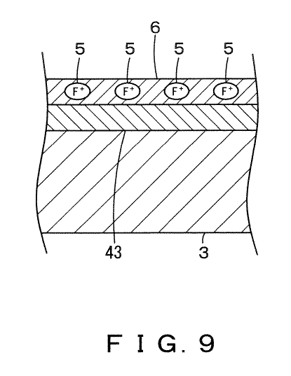

That is, the amorphous silicon film 2 can be laser annealed with the active fluoride 5 not being adhered to the surface of the amorphous silicon film 2 formed on the glass substrate 3 to reform the amorphous silicon film 2 into the polysilicon film 6. Therefore, as shown in FIG. 9, since the charges or the active fluoride 6 do not leave residuals in the polysilicon film 6 and the grain boundary, as shown in FIG. 6, the thin film transistor 53 formed by the polysilicon film 6 may have the desired threshold characteristics (Vₜₕ). Therefore, since the thin film transistor 53 having the desired TFT characteristics can be obtained, the generation of problems such as the defective image output and increase in power consumption of the liquid crystal display element 41 provided with the thin film transistor 53 can be prevented.

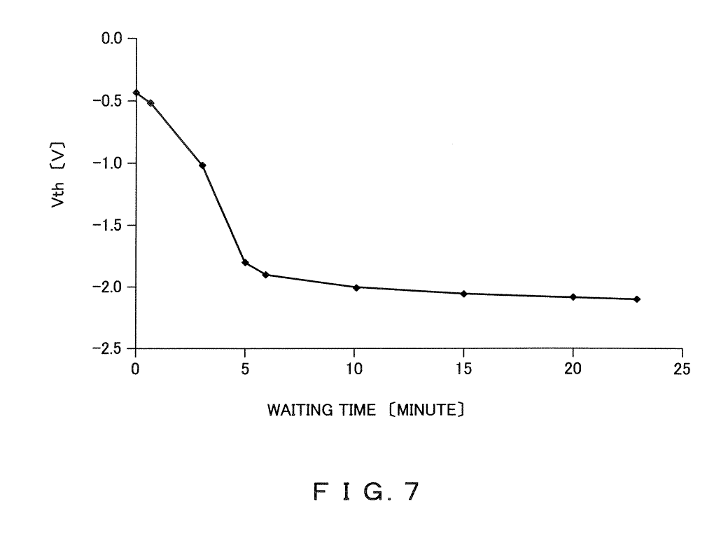

As shown in FIG. 7, the threshold characteristics of the thin film transistor 53 formed by the amorphous silicon film 2 formed on the glass substrate 3 made to wait in the waiting unit 26 are stabilized by setting the waiting time of the glass substrate 3 in the waiting unit 26 to 5 minutes or more. Furthermore, the threshold characteristics of the thin film transistor 53 formed on the glass substrate 3 can be further stabilized by setting the waiting time of the glass substrate 3 in the waiting unit 26 to 10 minutes or more.

Herein, the threshold characteristics of the thin film transistor 53 formed from the amorphous silicon film 2 formed on the glass substrate 3 can be further stabilized by making the glass substrate 3 wait for a longer period of time using the waiting unit 26. However, when the waiting time in the waiting unit 26 of the glass substrate 3 is made longer than 20 minutes, it takes too much time to manufacture the liquid crystal display element 41. The stability of the threshold characteristics of the thin film transistor 53 to the waiting time of the glass substrate 3 is hardly changed. Thereby, it is preferable that the waiting time in the waiting unit 26 of the glass substrate 3 is set to 10 minutes to 20 minutes.

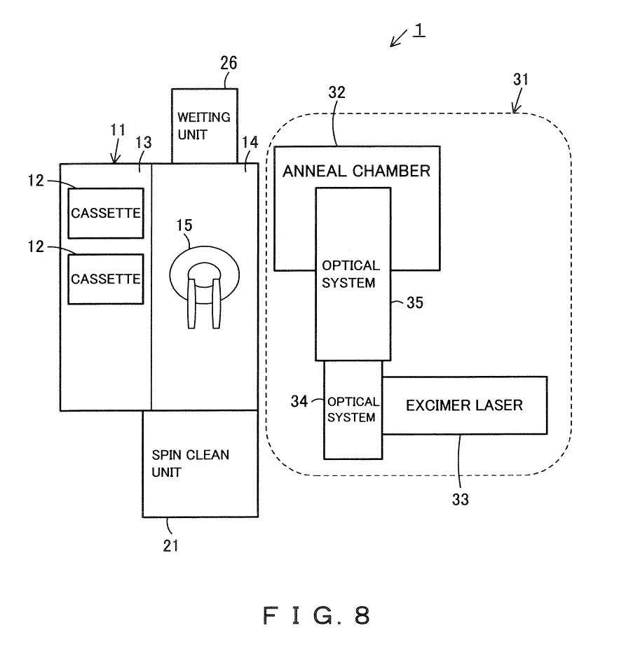

The waiting unit 26 is stored and attached in the cassette setting part 13 of the cassette station 11 in the above first embodiment. However, the waiting unit 26 can also be attached to the other end side of the substrate conveyance part 14 of the cassette station 11 as shown in the second embodiment shown in FIG. 8. The waiting unit 26 is attached to the other end side of the substrate conveyance part 14 of the opposite side to the side to which the spin clean unit 21 is attached. The glass substrate 3 spin cleaned by the spin clean unit 21 is conveyed into the waiting unit 26 from the inside of the spin clean unit 21 by the conveyance robot 15. The waiting unit 15 is attached to a position adjacent to the annealing chamber 32 of the laser annealing device 31. The glass substrate 3 made to wait in the waiting unit 15 is conveyed into the annealing chamber 32 via the conveyance robot 15.

As a result, since the glass substrate 3 in which the amorphous silicon film 2 is cleaned by the spin clean unit 21 is conveyed to the annealing chamber 32 of the laser annealing device 31 after the glass substrate 3 is made to wait in the waiting unit 26, and is laser annealed, the same operation effect as that of the above first embodiment can be exhibited. Since the waiting unit 26 can be easily attached to the existing composite type excimer laser annealing device 1 by attaching the waiting unit 26 to the other end part of the substrate conveyance part 14 of the cassette station 11, the versatility of the waiting unit 26 can be improved.

Except for a leaving type waiting unit 26 for leaving and making the glass substrate 3 to be conveyed wait, a drying type waiting unit 26 for ventilating, spraying and drying hot nitrogen gas and air to the amorphous silicon film 2 formed on the glass substrate 3, and a heated type waiting unit 26 for heating the amorphous silicon film 2 formed on the glass substrate 3 by an infrared lamp and a hot plate or the like can also be made to correspond and used.

Furthermore, a fluoride collecting means for collecting the fluoride sublimated in the waiting unit 26 can also be attached to the waiting unit 26. When the glass substrate 3 is made to wait by the waiting unit 26, in addition to the active fluoride 5 adhered to the surface of the amorphous silicon film 2 formed on the glass substrate 3, various substances having the plus charges adhered to the surface of the amorphous silicon film 2 can also be sublimated.

The waiting unit 26 is attached in the cassette setting part 13 of the cassette station 11 or to the other end side of the substrate conveyance part 14 of the cassette station 11. However, the waiting unit 26 may be attached to any position where the glass substrate 3 cleaned by the spin clean unit 21 can be conveyed into the annealing chamber 32 of the laser annealing device 31 after the glass substrate 3 is made to wait. The amorphous silicon film 2 formed on the glass substrate 3 is irradiated with the excimer laser beam by the laser annealing device 31. However, a YAG (Yttrium-Aluminum-Garnet) Laser is oscillated from the laser oscillating device 33 of the laser annealing device 31, and the amorphous silicon film 2 formed on the glass substrate 3 may be laser annealed by the YAG laser.

Although the configuration for conveying the glass substrate 3 made to wait by the waiting unit 26 to the laser annealing device 31 to laser anneal the glass substrate 3 is explained, even when the glass substrate 3 made to wait by the waiting unit 26 is conveyed to film control devices such as a plasma CVD (Chemical Vapor Deposition) device, a PVD (Physical Vapor Deposition) device and a sputtering device for depositing various thin films on the amorphous silicon film 2 of the glass substrate 3 to control the various thin films, the film control devices can be made to correspond and used.

Although the thin film transistor 53 using the polysilicon film 6 is explained, the switching elements such as the other Thin Film Diode (TFD) using the polysilicon film 6 can be made to correspond and used.

What is claimed is:

1. A film control method comprising:
a clean step of cleaning a surface of a silicon film provided on a substrate using a fluorine compound;
a sublimation step of sublimating fluoride contained in the fluorine compound adhered to the surface of the silicon film provided on the substrate cleaned by the clean step; and
a film control step of controlling the silicon film of the substrate in which the fluoride is sublimated in the sublimation step.

2. The film control method according to claim 1, wherein the clean step uses a hydrofluoric acid aqueous solution as the fluorine compound.

3. The film control method according to claim 1, wherein the silicon film is an amorphous silicon film, and the film control step is a laser annealing step of laser annealing the amorphous silicon film of the substrate to reform the amorphous silicon film into a polysilicon film.

4. The film control method according to claim 3, wherein the laser annealing step is an excimer laser annealing step of irradiating the amorphous silicon film of the substrate with an excimer laser to reform the amorphous silicon film into the polysilicon film.

5. The film control method according to claim 1, wherein the sublimation step is a step of sublimating a molecule having a plus charge on the surface of the silicon film of the substrate.

6. The film control method according to claim 5, wherein the sublimation step is a step of holding the substrate for at least 5 minutes or more to sublimate the molecule having the plus charge on the surface of the silicon film of the substrate.

7. The film control method according to claim 1, wherein the sublimation step is a step of sublimating active fluoride as a molecule having a plus charge on the surface of the silicon film of the substrate.

8. The film control method according to claim 1, wherein the sublimation step removes a charge adhered to the surface of the silicon film.

9. A film control device comprising:
a clean means for cleaning a silicon film provided on a substrate using a fluorine compound;
a sublimation means for a sublimating fluoride contained in the fluorine compound adhered to the silicon film of the substrate cleaned by the clean means; and
a film control means for controlling the silicon film of the substrate in which the fluoride is sublimated by the sublimation means.

10. The film control device according to claim 9, wherein the clean means uses a hydrofluoric acid aqueous solution as the fluorine compound.

11. The film control device according to claim 9, wherein the silicon film is an amorphous silicon film, and
the film control means is a laser annealing means for laser annealing the amorphous silicon film of the substrate to reform the amorphous silicon film into a polysilicon film.

12. The film control device according to claim 11, wherein the laser annealing means is a means for irradiating the amorphous silicon film of the substrate with an excimer laser to reform the amorphous silicon film into the polysilicon film.

13. The film control device according to claim 9, wherein the sublimation means is a means for sublimating a molecule having a plus charge on the surface of the silicon film of the substrate.

14. The film control device according to claim 13, wherein the sublimation means is a means for holding the substrate for at least 5 minutes or more to sublimate the molecule having the plus charge on the surface of the silicon film of the substrate.

15. The film control device according to claim 9, wherein the sublimation means is a means for sublimating active fluoride as the molecule having the plus charge on the surface of the silicon film of the substrate.

16. The film control device according to claim 9, wherein the sublimation means removes a charge adhered to the surface of the silicon film.

17. The film control device according to claim 9, wherein the clean means is a spin clean unit for cleaning the substrate while rotating the substrate.

18. The film control device according to claim 9, wherein the sublimation means is a waiting unit for making the substrate wait.

19. The film control device according to claim 9, wherein the film control means is a laser annealing device.
